(19) United States
(12) Patent Application Publication
(10) Pub. No.: US 2026/0214974 A1
(43) Pub. Date: Jul. 23, 2026

(54) INSULATED GATE BIPOLAR SUPERJUNCTION TRANSISTOR

(71) Applicant: Alpha and Omega Semiconductor International LP, Toronto (CA)

(72) Inventors: Wayne Wang, Sunnyvale, CA (US); Sandeep Sankaranarayanan, Palakkad (IN); Karthik Padmanabhan, Palo Alto, CA (US); Madhur Bobde, Sunnyvale, CA (US); Praveen Shenoy, Chandler, AZ (US)

(73) Assignee: Alpha and Omega Semiconductor International LP, Toronto (CA)

(21) Appl. No.: 19/026,952

(22) Filed: Jan. 17, 2025

(51) Int. Cl. H10D 84/82; H10D 62/00; H10D 62/10; H10D 84/01

(52) U.S. Cl. CPC H10D 84/82; H10D 62/054; H10D 62/111; H10D 84/0123

(57) ABSTRACT

Apparatus and associated methods relate to an insulated gate bipolar superjunction transistor (IGBST). In an illustrative example, a substrate having a predefined insulated gate bipolar transistor (IGBT) section and a metal-oxide-semiconductor field-effect transistor (MOSFET) section is provided. A number of layers of dopant to be implanted on the substrate, for example, is determined to form a superjunction structure across the IGBT section and the MOSFET section. For example, the number of layers may range from 1-15. In some implementations, for each layer of the superjunction structure, a layer of superjunction P columns through masked p+ implant and a corresponding layer of superjunction N columns through masked n+ implant are formed. For example, the superjunction P columns and the superjunction N columns are uniformly distributed across the substrate. Various embodiments may advantageously provide a smooth transition of output power from the IGBST between a low current to a high current input.

### TECHNICAL FIELD

Various embodiments relate generally to high-voltage power semiconductor devices and manufacturing technologies.

### BACKGROUND

Power conversion systems are essential technologies in modern electronics, used to efficiently convert electrical power from one form to another. These systems encompass a wide range of devices, including AC-DC converters, DC-AC inverters, DC-DC converters, and AC-AC converters, which are all designed to transform electrical energy to meet specific voltage, current, or frequency requirements. Power conversion systems are critical for applications in industrial, automotive, telecommunications, and consumer electronics, enabling the reliable distribution and utilization of energy across a broad spectrum of devices and infrastructure.

These systems are utilized for various purposes, depending on the specific power requirements of the application. Power conversion systems in renewable energy integrate variable power sources like solar panels and wind turbines into electrical grids, converting their output to a stable, grid-compatible form. In transportation, power converters are used in electric vehicles (EVs) for battery charging (AC-DC conversion) and motor control (DC-AC conversion), as well as regenerative braking, which converts kinetic energy back into stored electrical energy. Data centers and telecommunications infrastructure rely on power conversion systems to provide uninterrupted, stable power to equipment, converting grid AC power to the low-voltage DC power necessary for sensitive electronic devices.

In particular, high-power AC-DC converters and DC-AC inverters are essential components in renewable energy systems and electric vehicle infrastructure. For example, in solar energy systems, high-power DC-AC inverters are used to convert the DC output from solar panels to AC for grid feeding or local consumption. Similarly, high-power AC-DC converters in EV charging stations convert AC from the grid into the appropriate DC voltage for efficient battery charging. These systems must handle high currents and voltages while maintaining efficiency and minimizing losses, often requiring sophisticated control techniques to manage heat dissipation and ensure safe, reliable operation. The development of advanced materials like Silicon Carbide (SiC) and Gallium Nitride (GaN) in power devices has significantly enhanced the performance of these high-power conversion systems, allowing for higher efficiency and power density in a range of demanding applications.

### SUMMARY

Apparatus and associated methods relate to an insulated gate bipolar superjunction transistor (IGBST). In an illustrative example, a substrate having a predefined insulated gate bipolar transistor (IGBT) section and a metal-oxide-semiconductor field-effect transistor (MOSFET) section is provided. A number of layers of dopant to be implanted on the substrate, for example, is determined to form a superjunction structure across the IGBT section and the MOSFET section. For example, the number of layers may range from 1-15. In some implementations, for each layer of the superjunction structure, a layer of superjunction P columns through masked p+ implant and a corresponding layer of superjunction N columns through masked n+ implant are formed. For example, the superjunction P columns and the superjunction N columns are uniformly distributed across the substrate. Various embodiments may advantageously provide a smooth transition of output power from the IGBST between a low current to a high current input.

Various embodiments may achieve one or more advantages. For example, some embodiments may advantageously be having an outstanding Breakdown Voltage (BV) multiplied by On-Resistance (Rds(on)) Area Figure of Merit (FOM). Some embodiments may, for example, advantageously provide excellent linearity in conduction from low to moderate current levels. For example, some embodiments may advantageously have low conduction loss at high current level. Some embodiments, for example, may advantageously combine the advantages of the SJ-MOSFET and the IGBT devices. For example, some embodiments may advantageously achieve robust avalanche and/or short circuit ruggedness. Some embodiments may, for example, advantageously balance breakdown voltage of the IGBT section. For example, some embodiments may advantageously provide a mechanism to independently configure a first threshold voltage of the MOSFET section and a second threshold voltage of the IGBT section. Some embodiments, for example, may advantageously increase channel density to enhance carrier injection during conduction. For example, some embodiments may advantageously eliminate a shield plate in a gate structure. Some embodiments may, for example, advantageously improve diode reverse recovery.

The details of various embodiments are set forth in the accompanying drawings and the description below. Other features and advantages will be apparent from the description and drawings, and from the claims.

### BRIEF DESCRIPTION OF THE DRAWINGS

FIG. 1 depicts an exemplary Insulated Gate Bipolar Superjunction Transistor (IGBST) Device employed in an illustrative use-case scenario.

FIG. 2 is a schematic diagram depicting an exemplary IGBST without showing an insulation layer above the trench gate and a top metal layer.

FIG. 3 is a schematic diagram depicting an exemplary IGBST having a carrier lifetime control.

FIG. 4 is a schematic diagram depicting an exemplary IGBST having a localized radiation lifetime control.

FIG. 5A and FIG. 5B are schematic diagrams depicting exemplary trench gate IGBSTs without showing an insulation layer above the trench gate and a top metal layer.

FIG. 6A, FIG. 6B, FIG. 6C, FIG. 6D, FIG. 6E, FIG. 6F, FIG. 6G, FIG. 6H, FIG. 6I, FIG. 6J, and FIG. 6K depict various stages of an exemplary IGBST formation process.

FIG. 7 is a flowchart illustrating an exemplary superjunction formation method.

Like reference symbols in the various drawings indicate like elements.

### DETAILED DESCRIPTION OF ILLUSTRATIVE EMBODIMENTS

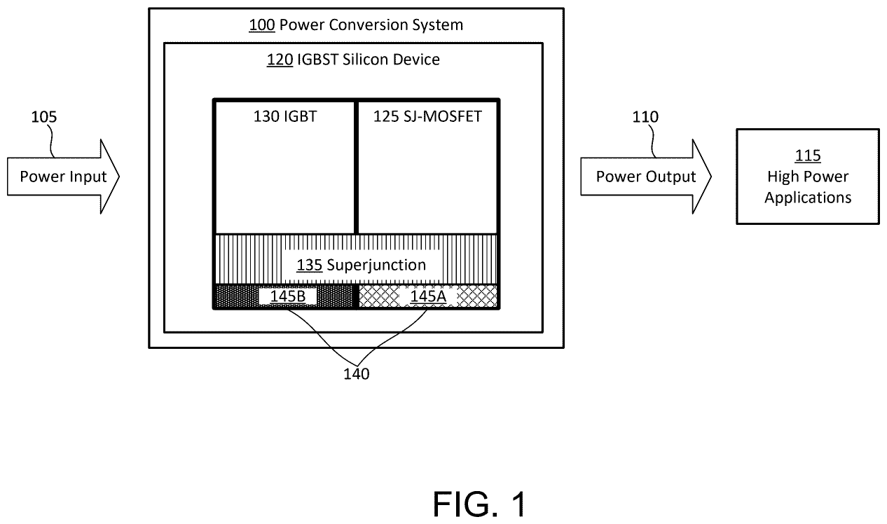

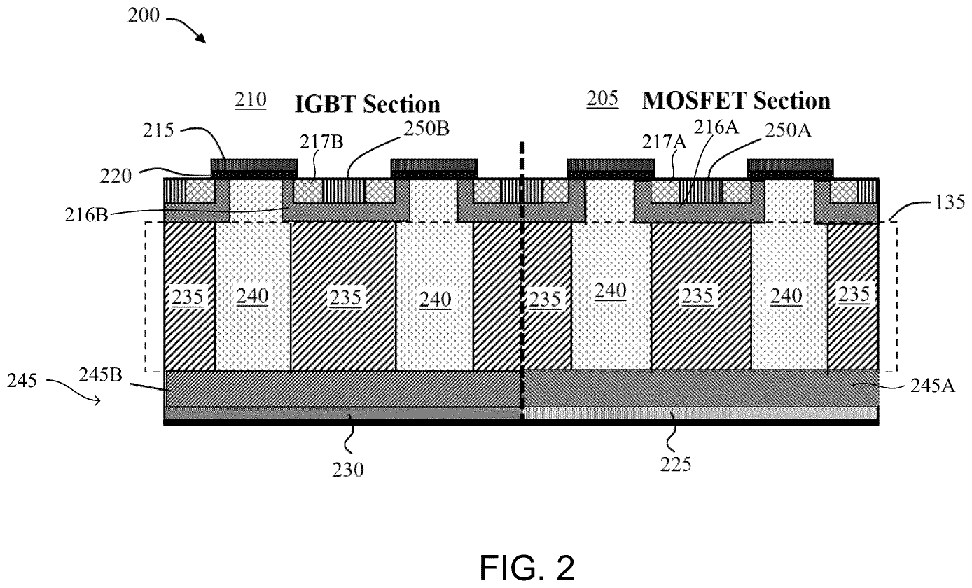

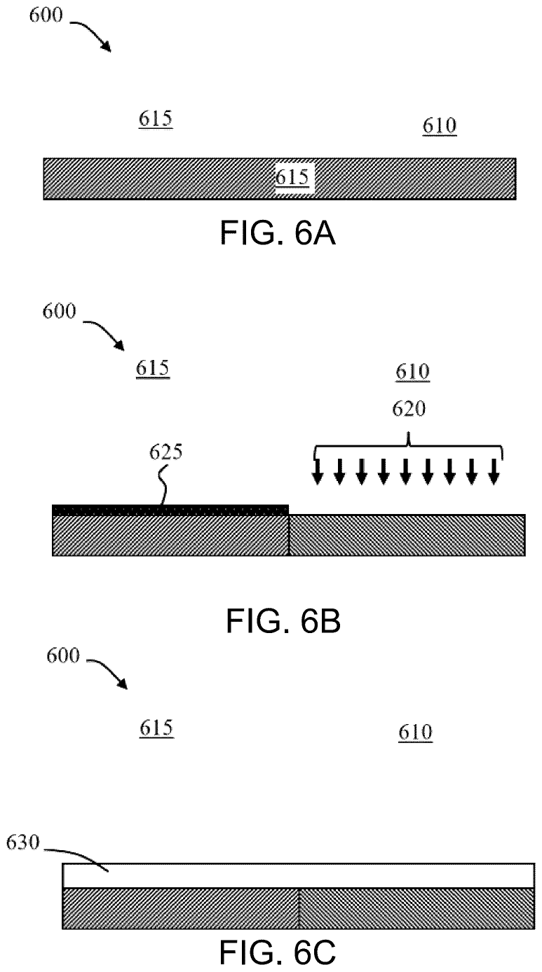

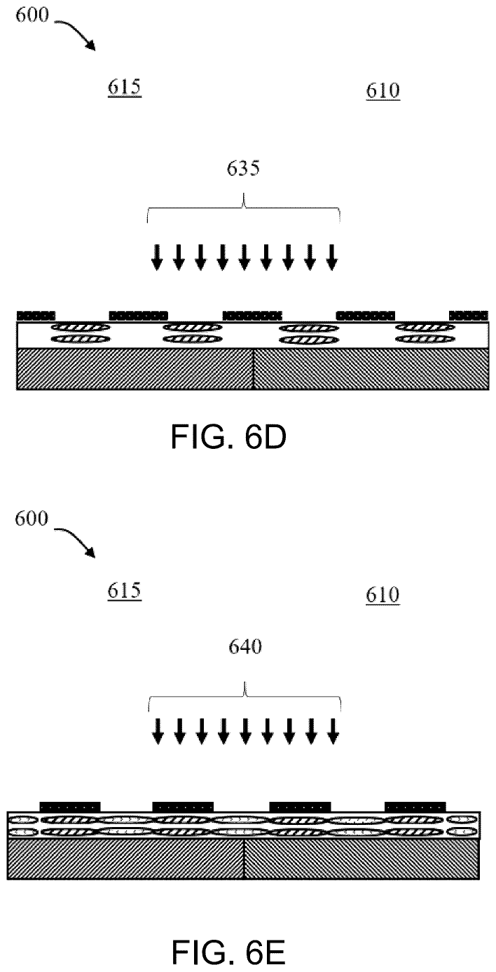

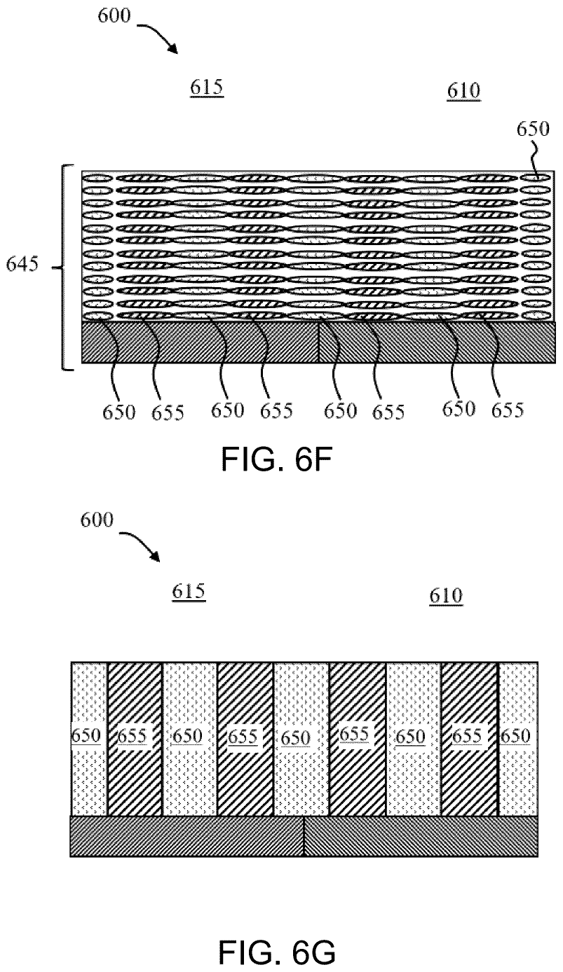

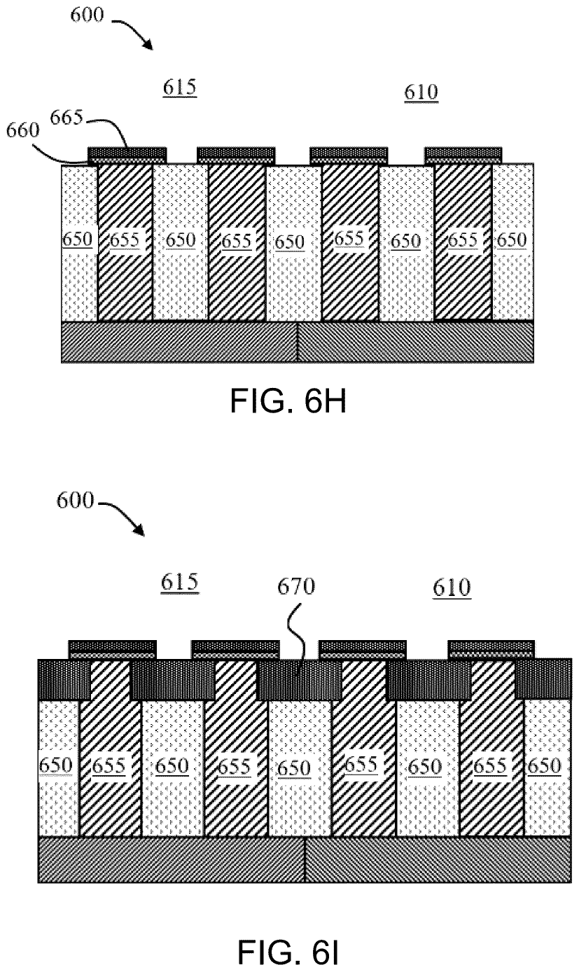

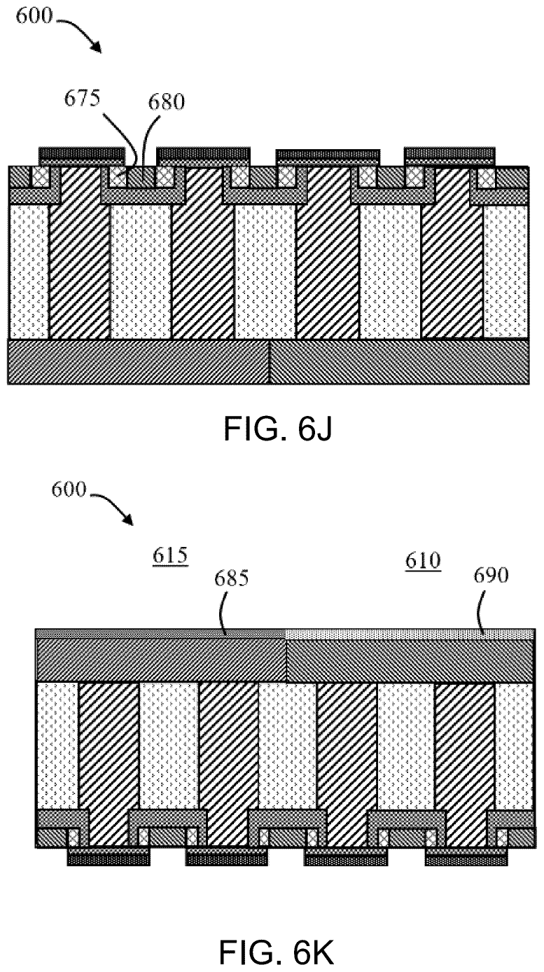

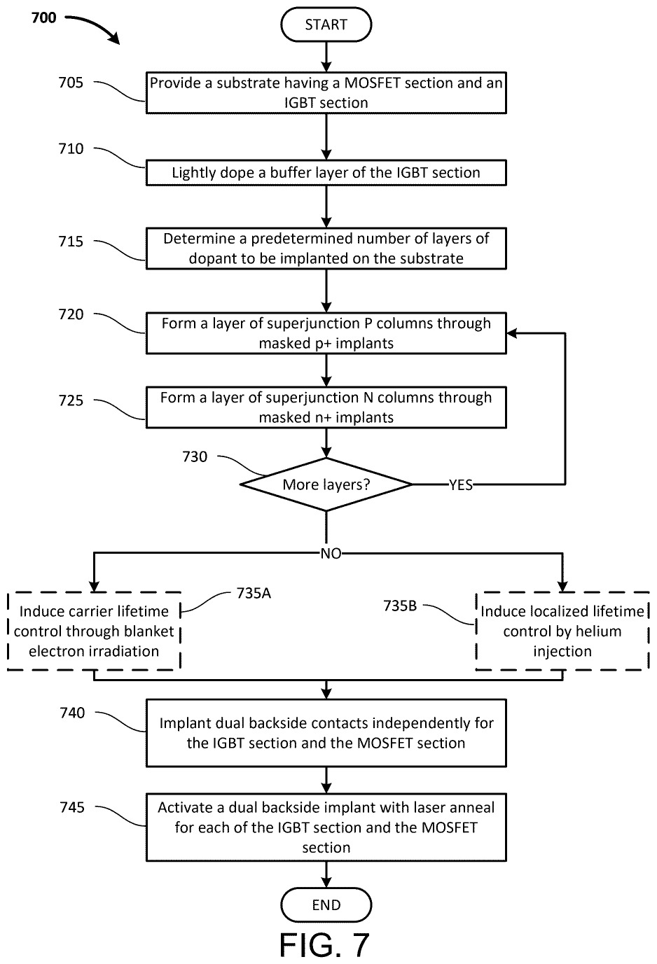

To aid understanding, this document is organized as follows. First, to help introduce discussion of various embodiments, an Insulated Gate Bipolar Superjunction Transistor (IGBST) is introduced with reference to FIG. 1. Second, that introduction leads into a description with reference to FIGS. 2-5 of some example embodiments of an IGBST. Third, with reference to FIGS. 6A-6K, a fabrication process is described in application to exemplary IGBSTs. Fourth, with reference to FIG. 7, the discussion turns to an illustrative method that illustrates an example superjunction formation. Finally, the document discusses further embodiments, example applications and aspects relating to IGBSTs.

FIG. 1 depicts an exemplary insulated gate bipolar superjunction transistor (IGBST) employed in an illustrative use-case scenario. In this example, a power conversion system 100 may receive a power input 105 to generate a power output 110 to a high power application 115. For example, the power input 105 may include alternating current (AC) from a grid, direct current (DC) from a renewable energy source such as solar panels, or energy from a battery storage system. In some implementations, the power input 105 may also include high-frequency AC power (e.g., from an industrial power supply).

For example, the power output 110 may be DC power suitable for charging electric vehicle batteries, AC power converted to drive industrial motors, or pulsed power for high-frequency heating systems. In some implementations, the power output 110 may be adapted to power telecommunication systems, server farms, or renewable energy integration infrastructure. The power conversion system 100 may, for example, operate as a high power AC-DC converter, a high power DC-AC inverter, and/or a high power DC-DC converter, depending on the specific requirements of the high power application 115. For example, the high power application 115 may include electric vehicle fast charging stations, large-scale industrial motor drives, or renewable energy storage systems. For example, the power input 105 may range from a low current to a high current. In some implementations, the input current value of the power input 105 may vary significantly. In some examples, the power conversion system 100 may advantageously maintain smooth transition at the power output 110 between a low current to a high current input.

In this example, the power conversion system 100 includes an IGBST silicon device 120. The IGBST silicon device 120, for example, may be a single silicon device. For example, the IGBST silicon device 120 may be a planar gate device. For example, the IGBST silicon device 120 may be a trench gate device.

As shown, the IGBST silicon device 120 includes a super-junction (SJ-MOSFET region 125) and an insulated gate bipolar transistor region (IGBT region 130). In some examples, an SJ-MOSFET and/or an IGBT may each be independently used for high-voltage semiconductor transistors. For example, the SJ-MOSFET region 125 may include one or more super-junction P/N columns. For example, the super-junction P/N columns may advantageously have an outstanding BV*RdsA FOM (Breakdown Voltage (BV) multiplied by On-Resistance (Rds(on)) Area Figure of Merit (FOM)). For example, the BV*RdsA FOM may be a performance metric used to evaluate the efficiency and effectiveness of power semiconductor devices. For example, the P/N columns charge balance design may advantageously provide excellent linearity in conduction from low to moderate current levels. The IGBT region 130, for example, may advantageously have low conduction loss at high current level (e.g., when a voltage across the collector and emitter terminals of the IGBT region 130 is higher than 26V) due to conductivity modulation.

In this example, the SJ-MOSFET region 125 and the IGBT region 130 are electrically coupled by a superjunction structure 135. For example, the superjunction structure 135 may include alternatively deposited and charge balanced superjunction P columns and N columns. For example, the superjunction P columns and N columns may be uniformly distributed in both the SJ-MOSFET region 125 and the IGBT region 130.

In various examples, the IGBST silicon device 120 may integrate the SJ-MOSFET region 125 and the IGBT region 130 in a single chip silicon device. A single chip silicon device may, for example, advantageously combine the advantages of both the SJ-MOSFET region 125 and the IGBT region 130. For example, the IGBST silicon device 120 may provide a smooth transition of the operation from low to high current level with overall favorable on-resistance. Accordingly, the IGBST silicon device 120 may, for example, improve efficiency for supplying power to the high power application 115.

In this example, the IGBST silicon device 120 includes a dual backside contacts structure (DBCS 140). For example, the DBCS 140 may be deposited at a backside of each of the SJ-MOSFET region 125 and the IGBT region 130. As shown, the DBCS 140 includes a first contact region 145A and a second contact region 145B. For example, the first contact region 145A and the second contact region 145B may be independently configured. In some implementations, the first contact region 145A may include a N+ contact. In some implementations, the second contact region 145B may include a P+ contact. In some examples, the DBCS 140 may improve device turn off loss.

FIG. 2 is a schematic diagram depicting an exemplary IGBST 200. For example, the IGBST 200 may be the IGBST silicon device 120 of FIG. 1. In this example, the IGBST 200 is a planar gate IGBST. In this example, the IGBST 200 includes a MOSFET section 205 and an IGBT section 210. As shown, each of the MOSFET section 205 and the IGBT section 210 includes two gate structures including one or more planar gates 215 deposited on top of a gate insulation layer 220. For example, the planar gates 215 may include polysilicon. For example, the gate insulation layer 220 may include oxide.

The MOSFET section 205 includes a first backside contact 225. In some implementations, the first backside contact 225 may include an N+contact layer. The IGBT section 210 includes a second backside contact 230. In some implementations, the second backside contact 230 may include a P+ contact layer. For example, the first backside contact 225 and/or the second backside contact 230 may be formed by dual backside implant (e.g., activated with laser anneal).

In this example, the IGBST 200 includes the superjunction structure 135. For example, the superjunction structure 135 may include uniformly distributed P columns 235 and N columns 240 across the MOSFET section 205 and the IGBT section 210.

In some implementations, the P columns 235 and the N columns 240 may be charge-balanced. For example, the P columns 235 may be formed through multiple layers of masked boron implants. In some implementations, the P columns 235 may include a graded doping concentration. For example, the doping concentration may be higher at near a top of the IGBST 200. For example, a graded doping concentration may advantageously achieve robust avalanche and/or short circuit ruggedness. For example, the N columns 240 may be formed by multiple layers of blanket or masked phosphorus implants. For example, the p columns 235 and the n columns 240 may be maintained with a substantially uniform width between 5-7 microns.

The IGBST 200 includes a buffer layer 245 underneath the P columns 235 and the N columns 240 of the superjunction structure 135. The buffer layer 245 is divided into a buffer region 245B in the IGBT section 210 less heavily doped than a buffer region 245A in the MOSFET section 205. For example, the buffer region 245B may be undoped. For example, the buffer region 245B may be lightly doped. In some examples, the buffer region 245B may advantageously balance breakdown voltage of the IGBT section 210. For example, the buffer layer 245 may mitigate electric field concentration and/or maintain a uniform voltage distribution across the IGBST 200.

As shown, the IGBST 200 includes source regions 217A and 217B disposed in body regions 216A and 216B respectively, and source body contacts 250A, 250B, respectively. For example, the first source region 217A, the first body region 216A and the first source body contact 250A may be formed for the MOSFET section 205. For example, the second source region 217B, the second body region 216B and the second source body contact 250B may be formed for the IGBT section 210. In some implementations, the first body region 216A and the second body region 216B may be independently implanted. For example, the first body region 216A and the second body region 216B may advantageously provide a mechanism to independently configure a first threshold voltage of the MOSFET section 205 and a second threshold voltage of the IGBT section 210.

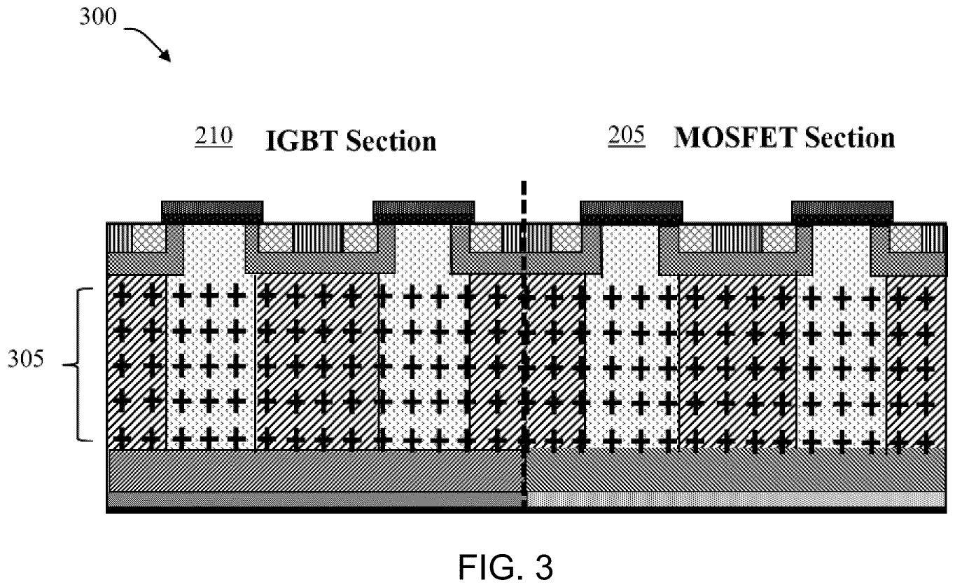

FIG. 3 is a schematic diagram depicting an exemplary IGBST having a carrier lifetime control. For example, the IGBST 200 may include blanket and/or localized lifetime control to improve diode reverse recovery performance.

In this example, an IGBST 300 includes the MOSFET section 205 and the IGBT section 210. In this example, the IGBST 300 includes a defect introduction 305 introduced through blanket electron irradiation. For example, the defect introduction 305 may include a uniformly distributed defect induced by electron irradiation (ER) over (e.g., a substantially large, an entire, a large portion of) an area below the body regions and above the buffer layers.

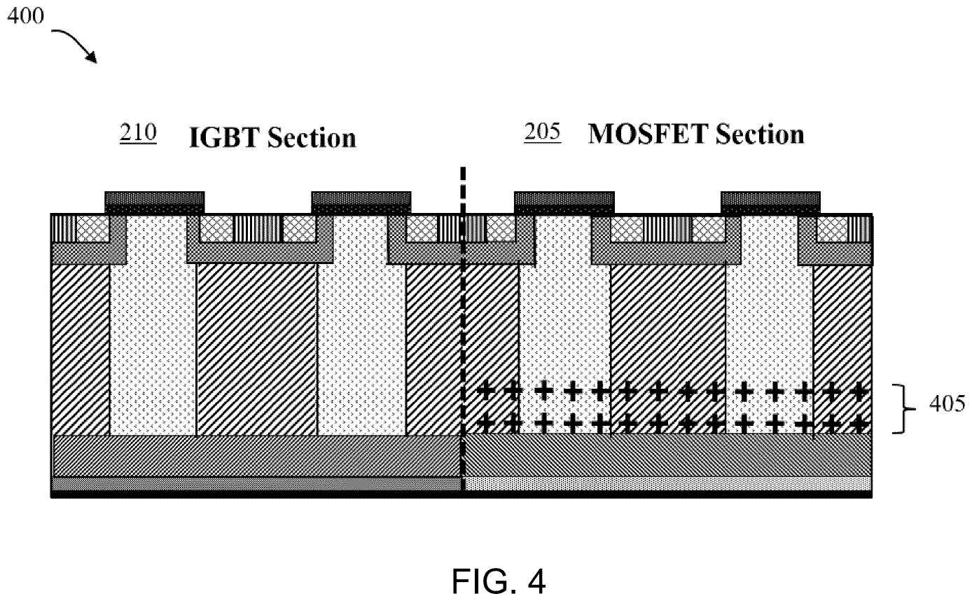

FIG. 4 is a schematic diagram depicting an exemplary IGBST having a localized radiation lifetime control. In this example, an IGBST 400 includes the MOSFET section 205 and the IGBT section 210. As shown, the MOSFET section 205 includes a localized carrier lifetime control 405 limited in a bottom portions of the P columns and N columns of the superjuction structure. For example, the localized carrier lifetime control 405 may be achieved by defect introduction through one or multiple time masked injection of proton or helium at the backside of the MOSFET section 205.

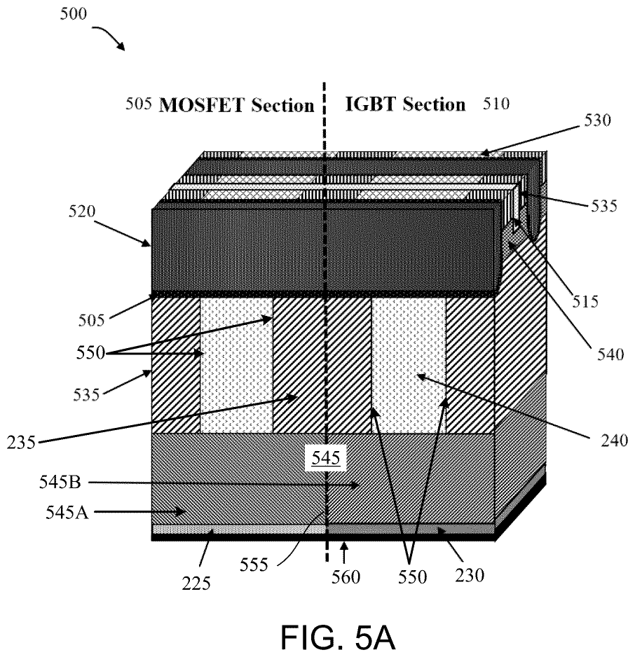

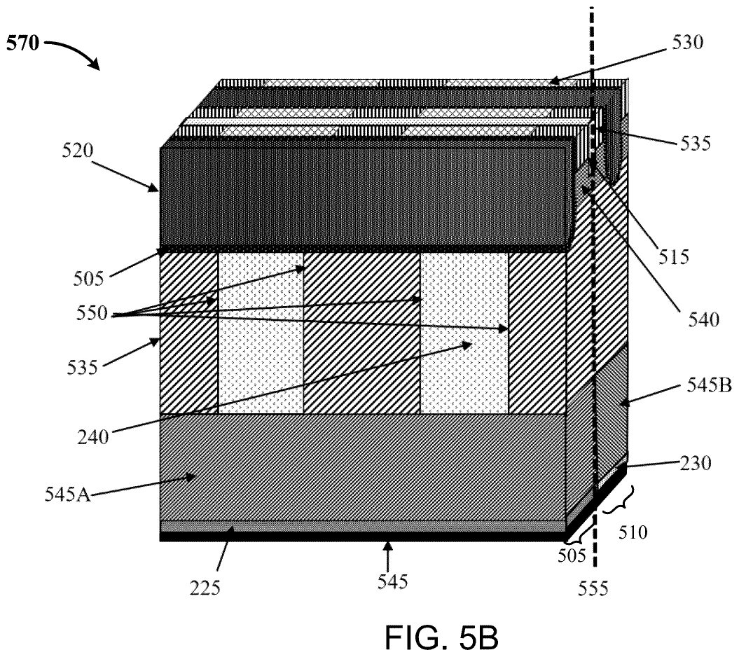

FIG. 5A and FIG. 5B are schematic diagrams depicting exemplary trench gate IGBSTs without showing an insulation layer above the trench gate and a top metal layer. FIG. 5A is a schematic diagram depicting an exemplary trench gate IGBST without showing an insulation layer above the trench gate and a top metal layer. In this example, a trench gate IGBST (TGIGBST 500) includes a MOSFET section 505 and an IGBT section 510 adjacent to the MOSFET section 505. The MOSFET section 505 includes a first backside contact 225. In some implementations, the first backside contact 225 may include an N+ contact layer. The IGBT section 510 includes a second backside contact 230. In some implementations, the second backside contact 230 may include a P+ contact layer. For example, the first backside contact 225 and/or the second backside contact 230 may be formed by dual backside implant (e.g., activated with laser anneal). A bottom metal layer 560 may be deposited on a bottom surface of the TGIGBST 500 covering both the first backside contact 225 and the second backside contact 230.

The TGIGBST 500 includes a buffer layer 545 overlaying the first backside contact 225 in the MOSFET section 505 and the second backside contact 230 in the IGBT second 510. The buffer layer 545 is disposed underneath the P columns 235 and the N columns 240 of the superjunction structure 135. The buffer layer 545 is divided into a buffer region 545A in the MOSFET section 505 and a buffer region 545B in the IGBT section 510. An interface between the buffer region 545A and the buffer region 545B is coplanar with an interface between the first backside contact 225 and the second backside contact 230. The buffer region 545B in the IGBT section 510 is less heavily doped than the buffer region 545A in the MOSFET section 505. For example, the buffer region 245B may be undoped. For example, the buffer region 545B may be lightly doped. In some examples, the buffer region 545B may advantageously balance breakdown voltage of the IGBT section 510. For example, the buffer layer 545 may mitigate electric field concentration and/or maintain a uniform voltage distribution across the TGIGBST 500.

As shown, the TGIGBST 500 includes the P columns 235 and the N columns 240 disposed on top of the buffer layer are arranged in an alternating sequence in a first direction. Each of the P columns 235 and the N columns 240 extends laterally in parallel in a second direction perpendicular to the first direction. In this example, interfaces 550 between the P columns 235 and the N columns 240 are parallel to an interface 555 between the buffer region 545A and the buffer region 545B. In some examples, the interface 555 between the buffer region 545A and the buffer region 545B may substantially align to a center face of one of the P columns 235. As shown in FIG. 5A, the TGIGBST 500 further includes one or more source body trench contacts 515, a plurality of trench gates 520, and a gate insulation layer 525 insulating the plurality of trench gates 520 from surrounding semiconductor regions. The trench gates 520 filling gate trenches etched from a top semiconductor surface into top portions of the P columns 235 and the N columns 240 and extend laterally through the MOSFET section 505 and the IGBT section 510. For example, the trench gates 520 may be laterally extending in the first direction such that the trench gates 520 are in an orthogonal direction to the superjunction structure 135 to decouple channel (e.g., a conductive region formed under the trench gate of the TGIGBST 500) and superjunction pitches (e.g., of the P columns 235 and the N columns 240). Various embodiments may advantageously increase channel density to enhance carrier injection during conduction.

As shown, the TGIGBST 500 includes heavily doped source regions 530, heavily doped body contact regions 535, and less heavily doped body regions 540. The less heavily doped body regions 540, in some implementations, may extend between adjacent trench gates to a depth shallower than the trench gates (e.g., across the semiconductor). The heavily doped source regions 530 and the heavily doped body contact regions 535 are, in this example, disposed alternatively in sequence along the trench gates on top of the less heavily doped body regions 540 in an entire area between adjacent trench gates. In some implementations, the heavily doped source regions 530 may be heavily doped with a conductivity opposite the body region and the body contact region. For example, the heavily doped source regions 530 may be n-type and the less heavily doped body regions 540 may be p-type. In some examples, the heavily doped source regions 530 may be vertically aligned to the N columns 240 of the superjuction structure. In some examples, the body contact regions 535 are vertically aligned to the P columns 235 of the superjunction structure. In some examples, the source regions 530 may be p-type. For example, the less heavily doped body regions 540 may be n-type.

As shown in FIG. 5A, the TGIGBST 500 includes a source body trench contact 515 disposed at a central position between adjacent trench gates extending through the source regions 530 and the body contact regions 535 into the body region 540. The source body trench contact 515 may run laterally in parallel to the trench gates 520, for example. For example, a metal layer may be further deposited on top of an insulation above the gate to form a source electrode (not shown). In some implementations, the source electrode may be formed without the source body trench contact 515.

FIG. 5B is another exemplary trench gate IGBST 570 similar to FIG. 5A. In example shown in FIG. 5B, an interface between the buffer region 545A and the buffer region 545B is coplanar with an interface between the first backside contact 225 and the second backside contact 230. Interfaces 550 between the P columns 235 and the N columns 240 are perpendicular to the interface between the buffer region 545A and the buffer region 545B. In one example, the interface between the buffer region 545A and the buffer region 545B substantially aligns to a center face of the source body trench contact 515. In some embodiments, the interface 555 between the buffer region 545A and the buffer region 545B may substantially align to a center of one of the trench gates (not shown) of the TGIGBST 570.

In some implementations, the trench gates 520 as described with reference to FIGS. 5A and 5B may be replaced by the planar gates 215 as described with reference to FIG. 2. Instead of forming trench gates into semiconductor regions, for example, the planar gates 215 may be formed on top surface of semiconductor regions and extend laterally through the MOSFET section 505 and the IGBT section 510. For example, the planar gates 215 may be laterally extending in a first direction such that the planar gates 215 are in an orthogonal direction to the superjunction structure 135 to decouple channel (e.g., a conductive region formed under the trench gate of the TGIGBST 500) and superjunction pitches (e.g., of the P columns 235 and the N columns 240). Various embodiments may advantageously increase channel density to enhance carrier injection during conduction. In addition, the carrier lifetime control techniques described in FIG. 3 and FIG. 4 can also be used for the TGIGBSTs in FIGS. 5A and 5B.

FIG. 6A, FIG. 6B, FIG. 6C, FIG. 6D, FIG. 6E, FIG. 6F, FIG. 6G, FIG. 6H, FIG. 6I, FIG. 6J, and FIG. 6K depict various stages of an exemplary IGBST formation process. As shown in FIG. 6A, a buffer layer 605 is provided with an epitaxial layer (Epi) as a first step of making a planar gate IGBST (PGIGBST 600). In this example, the PGIGBST 600 includes a MOSFET section 610 and an IGBT section 615. In some implementations, at this stage, the buffer layer 605 may be doped with a low concentration of dopants (e.g., a light phosphorus dope).

For example, an N-type Buffer Epi may be grown in the buffer layer 605 before the superjunction multiple epi growth. In some implementations, the buffer layer 605 may be undoped at this stage. In some implementations, for making a TGIGBT, the manufacturing process may start with a similar process of manufacturing a trench superjunction MOSFET.

As shown in FIG. 6B, the buffer layer 605 at the MOSFET section 610 is doped with a low concentration of dopants 620 (e.g., a light phosphorus dope). For example, the IGBT section 615 may be masked by a mask 625 in this stage. For example, the MOSFET section 610 may have a higher dopant concentration than the IGBT section 615 in the buffer layer 605.

The stages shown in FIGS. 6C-E are repeated for a predetermined number of times, each time for one layer of a superjunction structure (e.g., the superjunction structure 135). For example, P columns of the superjunction structure may be formed through multiple layers of masked boron implants. For example, N columns of the superjunction structure may be formed by multiple layers of blanket or masked phosphorus implants.

In some implementations, the superjunction structure may include 5 layers. In some implementations, the superjunction structure may include 6 layers. In some implementations, the superjunction structure may include 7 layers. In some implementations, the layers of the superjunction structure may range from 5-20 layers.

As shown in FIG. 6C, for an i-th Epi layer of the superjunction structure, an intrinsic Epi 630 is grown. For example each layer of the Epi may be 3-6 microns thick. Next, n-type dopants 635 (e.g., phosphorus) may implant as N columns on the (i-th) intrinsic Epi 630 of the superjunction structure. The P columns are masked in this example. In some implementations, the n-type dopant 635 may implant on the intrinsic Epi 630 a single time in this stage. In some implementations, the n-type dopant 635 may implant on the intrinsic Epi 630 multiple times in this stage.

As shown in FIG. 6E, p-type dopants 640 (e.g., Boron) may implant as P columns on the (i-th) intrinsic Epi 630 of the superjunction structure. The N columns are masked in this example. In some implementations, the p-type dopant 640 may implant on the intrinsic Epi 630 a single time in this stage. In some implementations, the p-type dopant 640 may implant on the intrinsic Epi 630 multiple times in this stage. After repeating processes shown in FIGS. 6C-E for the predetermined times, as shown in FIG. 6F, a superjunction structure 645 having a substantially uniformly distributed P columns 650 and N columns 655 is formed. In some implementations, the P columns 650 and N columns 655 may be distributed with a predetermined difference in width (e.g., within a predetermined threshold unless the column is in a boundary). For example, the P columns 650 and the superjunction structure 645 may be charge balanced. In some implementations, the superjunction structure 645 may be 30-50 microns thick.

As shown in FIG. 6G, the P columns 650 and the n columns 655 are formed. In some implementations, the P columns 650 and the n columns 655 may be formed using a temperature drive (e.g., a high-temperature diffusion process). As shown in FIG. 6H, a gate oxide 660 is grown and a gate poly 665 is formed.

As shown in FIG. 6I, a body implant (e.g., boron for P-type in N-channel MOSFETs or phosphorus for N-type in P-channel devices) may be introduced into a silicon substrate of the PGIGBST 600. For example, the process shown in FIG. 6I may include a body thermal drive to form a body region 670. In some implementations, the MOSFET section 610 and the IGBT section 615 may go through a same single body implant to achieve a same gate threshold voltage. In some implementations, additional masked body implants (e.g., by using a body block mask) may be added to provide a dual threshold voltage characteristic in the PGIGBST 600. For example, the masked body implant may be added to the IGBT section 615 to achieve higher threshold voltage in the IGBT section 615. As shown in FIG. 6J, source regions 675 and P+ contact regions 680 are implanted.

As shown in FIG. 6K, backside contacts are formed. For example, a wafer under processing may be flipped for backside implantation. In this example, a backside P+ contact 685 for the IGBT section 615 and a backside N+ contact 690 for the MOSFET section 610 are formed. In some implementations, the contact 685 and the contact 690 may be formed by dual backside implant and activated with laser anneal. For example, a process shown in FIG. 6K may use dual masks to form the contact 685 and the contact 690. In some implementations, electron irradiation and/or thermal annealing may be performed to achieve carrier lifetime control and/or lower reverse recovery charge. For example, additional processes of implanting hydrogen in the backside of the MOSFET section 610 may be performed to achieve localized lifetime control. In some implementations, the process may include a backside polishing step. For example, the PGIGBST 600 may undergo a back grinding process until the total thickness is between 60-70 microns before backside implants are carried out. A metallization process may follow to form a device backside electrode.

FIGS. 6H to 6J show the steps to form the top structure of a planar gate MOSFET shown in FIG. 2. Alternating processes may be carried out to form the top structure of a trench gate MOSFET shown in FIGS. 5A and 5B.

FIG. 7 is a flowchart illustrating an exemplary superjunction formation method 700. For example, the method 700 may be used for the IGBST silicon device 120, the IGBST 200, the IGBST 300, and/or the IGBST 400. In this example, the method 700 begins in step 705 when a substrate having a MOSFET section and an IGBT section is provided. For example, a silicon substrate may be supplied to a fabrication system configured to create the superjunction layers across the SJ-MOSFET region 125 and the IGBT region 130.

In step 710, a buffer layer of the IGBT section is lightly doped. For example, the buffer layer may be doped with phosphorus to achieve a light doping concentration. In step 715, a predetermined number of layers of dopant to be implanted on the substrate is determined. For example, a total thickness of 30-50 microns may be deposited in a single layer or in multiple layers (e.g., 2-20 layers). In some implementations, a resulting semiconductor device may have better performance when more layers are used in a manufacturing process.

After the number of layers of dopant is determined, a layer of superjunction P columns is formed through masked P+ implants in step 720. For example, the P+ regions may be implanted using a boron source. In some implementations, a patterned mask may be used to define the P columns. In step 725, a layer of superjunction N columns is formed through masked N+ implants. For example, phosphorus ions may be implanted in the regions not covered by the mask in step 720 to create the N columns. For example, the P columns and the N columns may be uniformly distributed.

At a decision point 730, it is determined whether more layers are needed. For example, the manufacturing processor may compare the number of formed P/N column layers with the predetermined number set in step 715. If more layers are required, the step 720 is repeated.

If no additional layers are needed, processes to form device top structure are carried out then steps 735A and/or 735B may be performed. In step 735A, a carrier lifetime control is induced through blanket electron irradiation. For example, an electron beam source may irradiate the device to introduce uniform defects, improving diode reverse recovery performance. In step 735B, a localized lifetime control is induced by helium injection. For example, a focused helium beam may create targeted defects in selected regions of the superjunction structure to fine-tune performance characteristics. In some examples, the localized lifetime control may be induced by proton injection. After the decision point 730, or, in some implementations, the step 735A and/or the step 735B, dual backside contacts are implanted independently for the IGBT section and the MOSFET section are implanted in step 740.

In step 745, a dual backside implant is activated with laser anneal for each of the IGBT section and the MOSFET section, and the method 700 ends. For example, a laser annealing may be performed to activate the P+ and N+ backside contacts and ensure optimal electrical performance. A backside metallization is then performed to form a backside electrode.

Although various embodiments have been described with reference to the figures, other embodiments are possible. Although an exemplary system has been described with reference to the figures, other implementations may be deployed in other industrial, scientific, medical, commercial, and/or residential applications.

Various examples of modules may be implemented using circuitry, including various electronic hardware. By way of example and not limitation, the hardware may include transistors, resistors, capacitors, switches, integrated circuits, other modules, or some combination thereof. In various examples, the modules may include analog logic, digital logic, discrete components, traces and/or memory circuits fabricated on a silicon substrate including various integrated circuits (e.g., FPGAS, ASICs), or some combination thereof. In some embodiments, the module(s) may involve execution of preprogrammed instructions, software executed by a processor, or some combination thereof. For example, various modules may involve both hardware and software.

In an illustrative aspect, a semiconductor transistor may include a first region configured as a MOSFET with a first threshold voltage. For example, the semiconductor transistor may include a second region configured as an IGBT with a second threshold voltage. For example, the semiconductor transistor may include a superjunction structure. For example, the super junction structure may include alternating columns of P columns and N columns uniformly distributed across the first region and the second region.

For example, the semiconductor transistor may include a dual backside contact structure may include a first contact may include a N+ contact disposed at a backside of the first region, and a second contact may include a P+ contact disposed at a backside of the second region. For example, the first region and the second region may be electrically coupled by the superjunction structure. For example, the first region and the second region may be integrated in a single chip semiconductor device.

For example, the semiconductor transistor may include a buffer region implemented underneath the second region. For example, the buffer region may be lightly doped. For example, a breakdown voltage of the semiconductor transistor may be balanced.

For example, a doping concentration of the P columns may be graded.

For example, the superjunction structure may include a uniformly distributed defect and/or a localized defect.

The semiconductor transistor, for example, may include a source body trench contact disposed between adjacent gates extending through a source region into a body region. For example, the semiconductor transistor may include a trench gate. For example, the trench gate may be disposed orthogonal to the alternating columns. For example, the trench gate and the superjunction structure may be decoupled.

In an illustrative aspect, a semiconductor transistor may include a first region configured as a MOSFET with a first threshold voltage. For example, the semiconductor transistor may include a second region configured as an IGBT with a second threshold voltage. For example, the semiconductor transistor may include a superjunction structure. For example, the superjunction structure may include alternating columns of P columns and N columns uniformly distributed across the first region and the second region. For example, the first region and the second region may be electrically coupled by the superjunction structure. For example, the first region and the second region may be integrated in a single chip semiconductor device.

The semiconductor transistor may include a buffer region implemented underneath the second region. For example, the buffer region may be lightly doped. For example, a breakdown voltage of the semiconductor transistor may be balanced.

For example, a doping concentration of the P columns may be graded. For example, the superjunction structure may include a uniformly distributed defect and/or a localized defect.

The semiconductor transistor, for example, may include a plurality of gates extending parallel in the first region and the second region. The semiconductor transistor, for example, may include alternating source regions and body contact regions disposed along the gates on top of a body region.

For example, the trench gate may be disposed orthogonal to the alternating columns. For example, the trench gate and the superjunction structure may be decoupled.

The semiconductor transistor may include a source body trench contact disposed at a central position between adjacent gates extending through the source regions and the body contact regions into the body region.

In an illustrative aspect, a superjunction structure implantation method may include provide a substrate having an IGBT section and a MOSFET section. The superjunction structure implantation method may include determine a predetermined number of layers of dopant to be implanted on the substrate across the IGBT section and the MOSFET section. For example, the superjunction structure implantation method may include, for each layer of implants, perform dual implant operations.

For example, the operations may include form a corresponding layer of superjunction P columns through masked p+ implants. For example, the operations may include form the corresponding layer of superjunction N columns through masked n+ implants. For example, the superjunction P columns and the superjunction N columns may be uniformly distributed across the substrate.

For example, the superjunction structure implantation method may include activate a dual backside implant with laser anneal for each of the IGBT section and the MOSFET section. For example, the IGBT section comprises a P+ contact, and the MOSFET section comprises a N+ contact. For example, the P+ contact and/or the N+ contact may be formed by the dual backside implant.

For example, the superjunction structure implantation method may include carrier lifetime control through blanket electron irradiation. For example, the superjunction structure implantation method may include induce localized lifetime control by helium injection.

For example, the superjunction structure implantation method may include implant dual body contacts independently for the IGBT section and the MOSFET section. For example, the predetermined number of layers may be between 5 and 15.

A number of implementations have been described. Nevertheless, it will be understood that various modifications may be made. For example, advantageous results may be achieved if the steps of the disclosed techniques were performed in a different sequence, or if components of the disclosed systems were combined in a different manner, or if the components were supplemented with other components. Accordingly, other implementations are contemplated within the scope of the following claims.

What is claimed is:

1. A semiconductor transistor comprising:
a first region configured as a MOSFET with a first threshold voltage;
a second region configured as an IGBT with a second threshold voltage;
a superjunction structure comprising alternating columns of P columns and N columns uniformly distributed across the first region and the second region; and,
a dual backside contact structure comprising a first contact comprising a N+ contact disposed at a backside of the first region, and a second contact comprising a P+ contact disposed at a backside of the second region, wherein the first region and the second region are electrically coupled by the superjunction structure, such that the first region and the second region are integrated in a single chip semiconductor device.

2. The semiconductor transistor of claim 1, further comprising a buffer region implemented underneath the second region, wherein the buffer region is lightly doped, such that a breakdown voltage of the semiconductor transistor is balanced.

3. The semiconductor transistor of claim 1, wherein a doping concentration of the P columns is graded.

4. The semiconductor transistor of claim 1, wherein the superjunction structure further comprises a uniformly distributed defect and/or a localized defect.

5. The semiconductor transistor of claim 1, further comprising a source body trench contact disposed at a central position between adjacent gates extends through a source region into a body region.

6. The semiconductor transistor of claim 1, further comprising a trench gate, wherein the trench gate is disposed orthogonal to the alternating columns, wherein the trench gate and the superjunction structure are decoupled.

7. A semiconductor transistor comprising:
a first region configured as a MOSFET with a first threshold voltage;
a second region configured as an IGBT with a second threshold voltage; and,
a superjunction structure comprising alternating columns of P columns and N columns uniformly distributed across the first region and the second region, wherein the first region and the second region are electrically coupled by the superjunction structure, such that the first region and the second region are integrated in a single chip semiconductor device.

8. The semiconductor transistor of claim 7, further comprising a buffer region implemented underneath the second region, wherein the buffer region is lightly doped, such that a breakdown voltage of the semiconductor transistor is balanced.

9. The semiconductor transistor of claim 7, wherein a doping concentration of the P columns is graded.

10. The semiconductor transistor of claim 7, wherein the superjunction structure further comprises a uniformly distributed defect and/or a localized defect.

11. The semiconductor transistor of claim 7, further comprises a plurality of gates extending in parallel in the first region and the second region.

12. The semiconductor transistor of claim 11, further comprises alternating source regions and body contact regions disposed along the plurality of gates on top of a body region.

13. The semiconductor transistor of claim 7, further comprising a trench gate, wherein the trench gate is disposed orthogonal to the alternating columns, wherein the trench gate and the superjunction structure are decoupled.

14. The semiconductor transistor of claim 12, further comprises a source body trench contact disposed between adjacent gates extending through the source regions and the body contact regions into the body region.

15. A superjunction structure implantation method comprising:
provide a substrate having an IGBT section and a MOSFET section;
determine a predetermined number of layers of dopant to be implanted on the substrate across the IGBT section and the MOSFET section; and,
for each layer of implants, perform dual implant operations comprising:
form a corresponding layer of superjunction P columns through masked p+ implants; and,
form the corresponding layer of superjunction N columns through masked n+ implants, such that the superjunction P columns and the superjunction N columns are uniformly distributed across the substrate.

16. The superjunction structure implantation method of claim 15, further comprises activate a dual backside implant with laser anneal for each of the IGBT section and the MOSFET section, wherein the IGBT section comprises a P+ contact, and the MOSFET section comprises a N+ contact, wherein the P+ contact and/or the N+ contact is formed by the dual backside implant.

17. The superjunction structure implantation method of claim 15, further comprises induce carrier lifetime control through blanket electron irradiation.

18. The superjunction structure implantation method of claim 15, further comprises induce localized lifetime control by helium injection.

19. The superjunction structure implantation method of claim 15, further comprises implant dual body contacts independently for the IGBT section and the MOSFET section.

20. The superjunction structure implantation method of claim 15, wherein the predetermined number of layers is between 5 and 15.
